(19) United States
(12) Patent Application Publication
(10) Pub. No.: US 2013/0234295 A1
(43) Pub. Date: Sep. 12, 2013

(54) SEMICONDUCTOR DEVICE AND METHOD OF MANUFACTURING SAME, WIRING BOARD AND METHOD OF MANUFACTURING SAME, SEMICONDUCTOR PACKAGE, AND ELECTRONIC DEVICE

(71) Applicants: NEC CORPORATION, Tokyo (JP); RENESAS ELECTRONICS CORPORATION, Kanagawa (JP)

(72) Inventors: Yoshimichi Sogawa, Tokyo (JP); Takao Yamazaki, Tokyo (JP); Ichirou Hazeyama, Tokyo (JP); Sakae Kitajou, Tokyo (JP); Nobuaki Takahashi, Kanagawa (JP)

(73) Assignees: RENESAS ELECTRONICS CORPORATION, Kanagawa (JP); NEC CORPORATION, Tokyo (JP)

(21) Appl. No.: 13/864,119

(22) Filed: Apr. 16, 2013

Related U.S. Application Data
(62) Division of application No. 11/722,702, filed on Jun. 22, 2007, now abandoned.

(30) Foreign Application Priority Data
Dec. 27, 2004 (JP) 2004-377760

(51) Int. Cl. H01L 23/48

(52) U.S. Cl. CPC H01L 23/481
USPC 257/621

(57) ABSTRACT

Passivation films 3a, 3b are formed to cover both surfaces of semiconductor substrate 1 which comprises terminal pads 2a, 2b on both surfaces. Openings 3c, 3d are provided at positions on passivation films 3a. 3b which match with terminal pads 2a, 2b. Throughholes 9 are formed inside of openings 3c, 3d to extend through terminal pad 2a, semiconductor substrate 1, and terminal pad 2b. Insulating layer 4 made of SiO₂, SiN, SiO, or the like is formed on the inner surfaces of throughholes 9. Buffer layer 5 made of a conductive adhesive is formed to cover insulating layer 4 and terminal pads 2a, 2b in openings 3c, 3d. Further, conductive layer 6 made of a metal film is formed on buffer layer 5 by electrolytic plating, non-electrolytic plating, or the like.

### TECHNICAL FIELD

The present invention relates to a semiconductor device including a through via and a method of manufacturing the same, a wiring board including a through via and a method of manufacturing the same, a semiconductor package which comprises such a semiconductor device, or such a wiring board, or both such a semiconductor and such a wiring board, and an electronic device which comprises this semiconductor package.

### BACKGROUND ART

With increasingly higher performance of electronic devices, a growing need exists for semiconductor devices having higher densities. In recent years, to respond to this need, strong progress has been made in developing semiconductor packages that incorporate high density by building a plurality of semiconductor chips into a single package, i.e., so-called multi-chip packages. Among these multi-chip packages, a stack type multi-chip package, which includes a plurality of semiconductor chips stacked in a thickness direction, is widely used because it can realize both an increase in performance and a reduction in the size of a semiconductor device. Also, in order to further increase the performance and reduce the size of the stack type multi-chip package, there has been developed a semiconductor package which is configured to three-dimensionally connect semiconductor chips to each other by interconnecting surface electrodes of one semiconductor chip with back electrodes of another semiconductor chip through a via which is formed through the semiconductor chip (for example, see Japanese Patent Application Laid-open No. 2001-60654 and Japanese Patent Application Laid-open No. 2000-260934).

FIG. 1 is a cross-sectional view illustrating the structure of a conventional semiconductor package described in Japanese Patent Application Laid-open No. 2001-60654. Semiconductor package 100 illustrated in FIG. 1 comprises a plurality of semiconductor devices 105 wherein elements including transistors, resistors, capacitors, and the like (not shown) and electrodes 102 are formed on semiconductor substrates 101. Semiconductor devices 105 are stacked with respective electrodes 102 aligned to one another. In semiconductor substrates 101 of these semiconductor devices 105, throughholes 106 which extend to the lower surfaces of electrodes 102 are formed. Insulating layer 104 made of silicon dioxide or the like is formed on the back surface of semiconductor device 101, i.e., the surface on which no elements are formed, and on the inner surfaces of throughholes 106. Each throughhole 106 is filled with conductive material 103 to form a through via. Then, semiconductor devices 105 adjoining in the vertical direction are connected by stacking a plurality of semiconductor devices 105 including the through vias, and by applying heat and pressure, to semiconductor devices 105.

Generally, solder, conductive adhesive, and the like are used as conductive material 103 that is filled in throughholes 106. When solder is used as conductive material 103, electric resistance within the through vias can be reduced and can provide a large bonding force. On the other hand, when a conductive adhesive is used as conductive material 103, heating is not required, thus making it possible to simplify the process and avoid damage due to heat. Since each semiconductor chip can be electrically connected without using wires by designing semiconductor package 100 into such a structure, a reduction in size and thickness and an increase in frequency can be accomplished as compared with conventional methods.

Japanese Patent Application Laid-open No. 2001-60654 also discloses a semiconductor package in which through vias are formed in a plurality of semiconductor devices after the semiconductor devices have been stacked, rather than a plurality of semiconductor devices in which through vias have been previously formed before the semiconductor devices are stacked. FIGS. 2 and 3 are cross-sectional views illustrating the structures of other conventional semiconductor packages 110, 120 which are described in Japanese Patent Application Laid-open No. 2001-60654. Semiconductor package 110 illustrated in FIG. 2 is manufactured in the following manner. First, a plurality of semiconductor devices 115 are stacked so as to match the positions of respective electrodes 112 formed on the surfaces thereof with one another. Subsequently, throughholes 116 are formed through semiconductor substrates 111 and electrodes 112 using a laser or the like. Then, after forming insulating layer 114 on the inner surfaces of portions of throughholes 116 formed in semiconductor substrates 111, metal film 113 is formed on the entire inner surfaces of throughholes 116 by vapor deposition, plating, or the like. In this way, a plurality of semiconductor devices 115 are electrically connected.

On the other hand, semiconductor package 120 illustrated in FIG. 3 is manufactured in the following manner. Two semiconductor devices 125 are stacked with their back surfaces opposing each other. After forming throughholes 126 through semiconductor substrates 121 and electrodes 122, insulating layer 124 is formed in portions of throughholes 126 formed in semiconductor substrates 121. Further, metal film 123 is formed on the entire inner surfaces of throughholes 126. In this way, two semiconductor devices 125 are electrically connected to each other.

Semiconductor packages 110, 120 structured as illustrated in FIGS. 2 and 3 can also simplify the manufacturing process even if an increased number of semiconductor devices are stacked because through vias can be collectively formed in a plurality of semiconductor devices.

Further, Japanese Patent Application Laid-open No. 2001-60654 also discloses a semiconductor device which includes through vias which are constructed by filling throughholes with a conductive adhesive as a conductive material. FIG. 4 is a cross-sectional view illustrating the structure of another conventional semiconductor package 130 described in Japanese Patent Application Laid-open No. 2001-60654. Semiconductor package 130 illustrated in FIG. 4 is manufactured in the following manner. First, a plurality of semiconductor devices 135 are stacked. Semiconductor device 135 has passivation film 137 formed on a surface of semiconductor substrate 131 to cover an element forming area (not shown). Then, throughholes 136 are formed through semiconductor substrates 131 and electrodes 132. After forming insulating layer 134 only on inner surfaces of portions of throughholes 136 that extend through semiconductor substrates 131, throughholes 136 are filled with conductive adhesive 133. In this way, respective semiconductor devices 135 are electrically connected.

As a method of forming through vias, other than the method described above, there is also a method which forms a seed layer, which excels in adherence, on the inner surfaces of throughholes by a CVD (Chemical Vapor Deposition) method, a sputtering method, or the like, and then filling a interior of the throughholes with a conductive material such as a metal by electrolytic plating.

However, the aforementioned related art has problems described below. For example, with through vias filled with a conductive adhesive in throughholes, a significant amount of resin is contained in the conductive adhesive, giving rise to the problem that there is an extremely large electric resistance, as compared with a metal film, which is difficult to reduce. Also, the conductive adhesive hardens and contracts when it hardens, which leads to another problem in which it is difficult to increase the thickness, thus making it difficult to fill the entire throughholes with conductive adhesive.

According to a method which combines a CVD method or a sputtering method with electrolytic plating, it is possible to form a highly adhesive conductive film on the inner surfaces of throughholes. However, a problem arises in that the through vias cannot be formed at a low cost because the CVD method and sputtering method require expensive facilities.

On the other hand, non-electrolytic plating is characterized by the ability to form a conductive film on the inner surfaces of throughholes at a low cost because it does not use expensive facilities. Disadvantageously, however, this method cannot form a highly adherent conductive film and creates a connection that has extremely low reliability, as compared with deposition methods such as the CVD method, sputtering method, and the like. In particular, a through via formed through a semiconductor chip has a conductive layer, which has a relatively large thickness, on a thin insulating layer formed on the inner surface of a throughhole, thus giving rise to a problem in which the conductive layer tends to peel off due to residual stress of the film itself and due to thermal stress caused by a difference in the coefficient of thermal expansion between the semiconductor substrate and the conductive layer.

### DISCLOSURE OF THE INVENTION

In view of the problems described above, it is an object of the present invention to provide a reliable semiconductor device which includes a conductive layer that is formed on the inner surfaces of throughholes and that is hard to peel off, and a method of manufacturing the same, a wiring board and a method of manufacturing the same, a semiconductor package, and an electronic device.

A semiconductor device of the present invention is characterized by comprising a semiconductor substrate, a first terminal pad formed on a surface of the semiconductor substrate, a throughhole extending through the first terminal pad and the semiconductor substrate in a thickness direction thereof, a buffer layer made of a resin and formed to extend from an inner surface of the throughhole to the surface of the semiconductor substrate, and a conductive layer formed to cover the buffer layer.

A wiring board of the present invention is characterized by comprising a wiring board body, a first terminal pad formed on a surface of the wiring board body, a throughhole extending through the first terminal pad and the wiring board body in a thickness direction thereof, a buffer layer made of a resin and formed to extend from an inner surface of the throughhole to the surface of the wiring board body, and a conductive layer formed to cover the buffer layer.

According to the semiconductor device or the wiring board of the present invention in the configurations as described above, since the buffer layer made of a resin is formed-between the insulating layer and the conductive layer, the conductive layer can be prevented from peeling off due to thermal stress caused by a difference in the coefficient of thermal expansion between the semiconductor substrate or the wiring board body and the conductive layer, and due to residual stress upon formation of the conductive layer, thereby improving reliability.

In these configurations, the buffer layer may comprise a conductive resin which contains a metal filler, and the buffer layer may intervene between the conductive layer and the first terminal pad, such that the conductive layer and the first terminal pad are electrically connected through the buffer layer. This increases the adherence of the buffer layer with the inner surface of the throughhole and the conductive layer, thus improving the effect of preventing the conductive layer from peeling off. Also, the conductive layer may extend from above the buffer layer to the first terminal pad, and the conductive layer may be directly in contact with the first terminal pad. In this way, resistance can be reduced within the throughhole. Further, the conductive layer may be formed of the same metal as metal filler or an alloy which includes the same metal as metal filler. Furthermore, the metal filler may include a material whose catalytic activity affects a reducing agent of non-electrolytic plating. This further improves adherence of the conductive layer with the buffer layer. Furthermore, the metal filler may have a grain diameter of 1 μm or less. In this way, the buffer layer can be readily formed even if the throughhole has a small diameter.

Alternatively, the buffer layer may have insulating properties, and the conductive layer may extend from above the buffer layer to the first terminal pad, and the conductive layer may directly in contact with the first terminal pad. In this way, since general resin can be used as the buffer layer, the material can be chosen from wider range of materials, and the cost can be reduced. Preferably, the buffer layer has asperities which are formed on a surface closer to the conductive layer. This can improve adherence of the buffer layer with the conductive layer.

In this semiconductor device or wiring board, an insulating layer formed on the inner surface of the throughhole may intervene between the buffer layer and the inner surface of the throughhole. Also, when a second terminal pad is formed at a position on the back surface of the semiconductor substrate or wiring board body, in alignment to the first terminal pad, the throughhole may be formed to extend through the first terminal pad, the semiconductor substrate or wiring board body, and the second terminal pad, and the buffer layer may be formed to extend from the inner surface of the throughhole to both the front and back surfaces of the semiconductor substrate or wiring board body. In other words, the buffer layer may be formed to cover at least part of the first terminal pad, at least part of the second terminal pad, and the insulating layer. In this event, the conductive layer may extend from above the buffer layer to the second terminal pad, and the conductive layer may be directly in contact with the second terminal pad. In this way, resistance can be reduced within the throughhole.

Further, when the buffer layer is formed of a resin whose elastic modulus is 1 Gpa or less, the conductive layer can be largely prevented from peeling off due to thermal stress and residual stress, thereby further improving reliability. Furthermore, the conductive layer may be formed in a tubular shape. This can reduce manufacturing time and cost.

A semiconductor package of the present invention is characterized by comprising a plurality of semiconductor devices in the configuration described above, which are stacked therein. Also, another semiconductor package of the present invention is characterized by comprising a plurality of wiring boards in the configuration described above, which are stacked therein, wherein the stacked wiring boards are electrically connected to at least one semiconductor device. In the present invention, reliability is improved more than in conventional semiconductor packages because of the use of the semiconductor device or wiring board which discourages the conductive layer from peeling off.

An electronic device of the present invention is characterized by comprising the semiconductor package described above. This electronic device is, for example, a mobile telephone, a notebook type personal computer, a desktop type personal computer, a liquid crystal device, an interposer, or a module.

A method of manufacturing a semiconductor device of the present invention is characterized by comprising the steps of forming a throughhole to extend through a semiconductor substrate and a terminal pad formed on a surface of the semiconductor substrate in a thickness direction thereof, forming a buffer layer made of a resin to extend from an inner surface of the throughhole to a surface of the terminal pad, and forming a conductive layer to cover the buffer layer.

A method of manufacturing a wiring board of the present invention is characterized by comprising the steps of forming a throughhole which extends through a wiring board body and a terminal pad formed on a surface of the wiring board body in a thickness direction thereof, forming a buffer layer made of a resin to extend from an inner surface of the throughhole to a surface of the terminal pad, and forming a conductive layer to cover the buffer layer.

According to these manufacturing methods, since the buffer layer made of a resin is formed between the insulating layer and conductive layer, the conductive layer can be prevented from peeling off due to thermal stress caused by a difference in the coefficient of thermal expansion between the semiconductor substrate or wiring board body and conductive layer, and due to residual stress upon formation of the conductive layer. Thus, it is possible to manufacture a highly reliable semiconductor device or wiring board.

The buffer layer may be formed of a conductive resin which contains a metal filler. Also, when metal filler includes a material whose catalytic activity affects to a reducing agent of non-electrolytic plating, the conductive layer can be formed by non-electrolytic plating. Further, the metal filler may have a grain diameter of 1 μm or less.

Alternatively, the buffer layer may be formed of an insulating resin, and the conductive layer may be formed to extend from above the buffer layer to the terminal pad, the conductive layer may be directly brought into contact with the terminal pad, and asperities may be formed on a surface of the buffer layer closer to the conductive layer.

Also, after forming the throughhole, an insulating layer may be formed on the inner surface of the throughhole, and a buffer layer may be formed on the insulating layer. Further, the buffer layer may be formed using a resin whose elastic modulus is 1 GPa or less. In this way, the conductive layer is less likely to peel off, thus improving reliability. Furthermore, the conductive layer may be formed by plating. In this way, the conductive layer can be formed at a low cost.

### BRIEF DESCRIPTION OF THE DRAWINGS

FIG. 1 A cross-sectional view illustrating the structure of a related semiconductor package.

FIG. 2 A cross-sectional view illustrating the structure of another related semiconductor package.

FIG. 3 A cross-sectional view illustrating the structure of a further related semiconductor package.

FIG. 4 A cross-sectional view illustrating the structure of a further related semiconductor package.

FIG. 5A A cross-sectional view illustrating the structure of a semiconductor device according to a first exemplary embodiment of the present invention.

FIG. 5B An enlarged view illustrating a through via of the semiconductor device according to the first exemplary embodiment of the present invention.

FIG. 6A A cross-sectional view illustrating a method of manufacturing the semiconductor device according to the first exemplary embodiment of the present invention showing the sequence of each manufacturing step.

FIG. 6B A cross-sectional view illustrating the method of manufacturing the semiconductor device according to the first exemplary embodiment of the present invention showing the sequence of each manufacturing step.

FIG. 6C A cross-sectional view illustrating a method of manufacturing the semiconductor device according to the first exemplary embodiment of the present invention showing the sequence of each manufacturing step.

FIG. 6D A cross-sectional view illustrating a method of manufacturing the semiconductor device according to the first exemplary embodiment of the present invention showing the sequence of each manufacturing step.

FIG. 7 A cross-sectional view illustrating the structure of a semiconductor device according to a second exemplary embodiment of the present invention.

FIG. 8 A cross-sectional view illustrating the structure of a semiconductor device according to a third exemplary embodiment of the present invention.

FIG. 9 A cross-sectional view illustrating the structure of a semiconductor device according to a fourth exemplary embodiment of the present invention.

FIG. 10A A cross-sectional view illustrating a method of manufacturing the semiconductor device according to the fourth exemplary embodiment of the present invention showing the sequence of each manufacturing step.

FIG. 10B A cross-sectional view illustrating a method of manufacturing the semiconductor device according to the fourth exemplary embodiment of the present invention showing the sequence of each manufacturing step.

FIG. 10C Across-sectional view illustrating a method of manufacturing the semiconductor device according to the fourth exemplary embodiment of the present invention showing the sequence of each manufacturing step.

FIG. 11A A cross-sectional view illustrating the structure of a semiconductor device according to a fifth exemplary embodiment of the present invention.

FIG. 11B An enlarged view illustrating a through via of the semiconductor device according to the fifth exemplary embodiment of the present invention.

FIG. 12 A cross-sectional view illustrating the structure of a semiconductor package according to a sixth exemplary embodiment of the present invention.

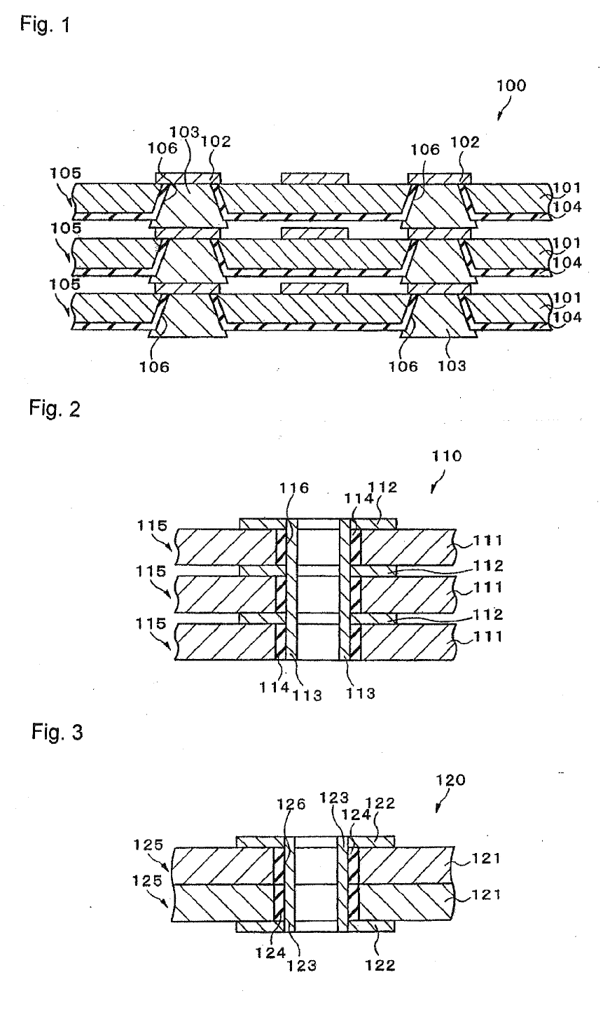

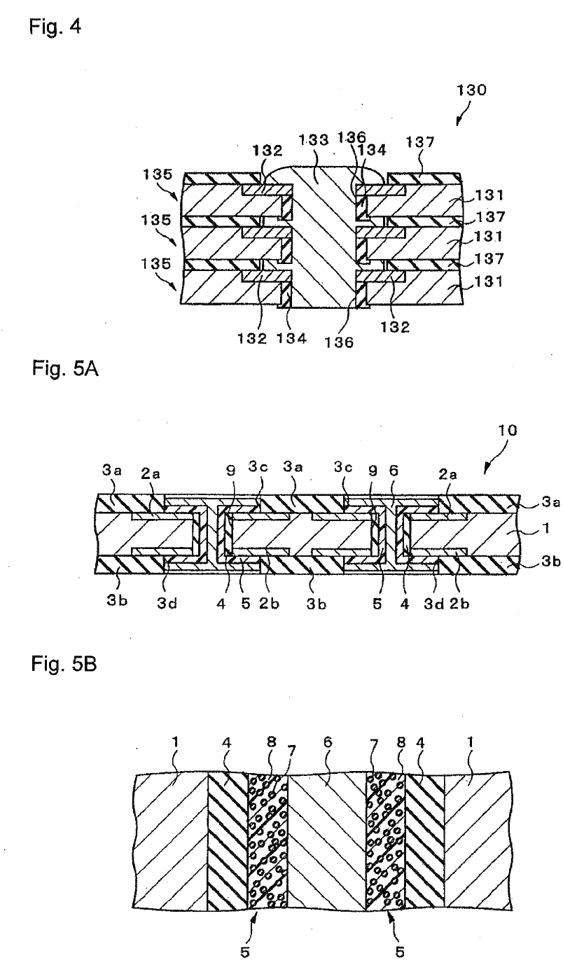

### BEST MODE FOR CARRYING OUT THE INVENTION

In the following, exemplary embodiments of the present invention will be described in a specific manner with reference to the accompanying drawings. First, a description will be given of a semiconductor device according to a first exemplary embodiment of the present invention. FIG. 5A is across-sectional view illustrating the structure of the semiconductor device according to the first exemplary embodiment of the present invention, and FIG. 5B is an enlarged view illustrating a through via thereof. The semiconductor device described in this specification refers to general semiconductor integrated circuits, and can be defined as LSIs including DRAM, SRAM, flash memory, logic, ASIC, and the like.

As illustrated in FIG. 5A, in semiconductor device 10 of this exemplary embodiment, terminal pad 2a and terminal pad 2b are formed at positions aligned to each other through insulating layers (not shown) on both surfaces of semiconductor substrate 1 on which elements (not shown) are formed. Also, passivation films 3a and 3b are formed to cover the front and back surfaces of semiconductor substrate 1, respectively. Openings 3c and 3d are formed through passivation films 3a and 3b in areas immediately above terminal pads 2a and 2b, respectively. Then, throughholes 9 are formed through terminal pad 2a, semiconductor substrate 1, and terminal pad 2b such that openings 3c and 3d are connected. Insulating layer 4 made of SiO₂, SiN, SiO, or the like is formed on the inner surfaces of throughholes 9. Then, buffer layer 5 made of a conductive adhesive is formed to cover insulating layer 4, and to cover terminal pads 2a and 2b in openings 3c and 3d. Further, a conductive layer 6 made of a metal film is formed to cover this buffer layer 5. Conductive layer 6 is formed to fill in crevices of throughholes 9 after insulating film 4 and buffer layer 5 have been formed on the surface in this order. In this way, through vias are formed through terminal pad 2a, semiconductor substrate 1, and terminal pad 2b.

As illustrated in FIG. 58, buffer layer 5 in semiconductor device 10 of this exemplary embodiment is formed of a conductive adhesive which has metal filler 7 dispersed in binder resin 8 so as to achieve a sufficient adherent strength to insulating layer 4 and conductive layer 6. The proportion of metal filler 7 within buffer layer 5 is, for example, between 40 and 95% by mass. When buffer layer 5 contains a larger amount of binder resin 8 so that the content of metal filler 7 is less than 40% by mass, buffer layer 5 has improved in adherent strength with insulating layer 4 but exhibits a larger electric resistance and a lower adherent strength to conductive layer 6. On the other hand, when the content of metal filler 7 exceeds 95% by mass, buffer layer 5 has improved in adherent strength with conductive layer 6, but is reduced in adherent strength with insulating layer 4 due to the insufficient content of binder resin 8. Materials available for metal filler 7 included in buffer layer 5 can be, for example, a metal such as Ag, Ni, Pd, Cu, Au, or the like, or an alloy material thereof. On the other hand, binder resin material 8 is preferably made of a lowly elastic material, whose elastic modulus of which is 1 GPa or less, including, for example, epoxy-based resin, acrylic-based resin, polyimide-based resin, urethane-based resin, polyester-based resin, bismuth imide-based resin, styrene-based resin, polyvinyl chloride-based resin, nylon-based resin, polyethylene-based resin, polypropylene-based resin, acid anhydride-based resin, fluoro-based resin, phenol-based resin, silicone-based resin, fluorine silicone-based resin, and the like. Since this can exemplary alleviate stress caused by a difference in the coefficient of thermal expansion between semiconductor substrate 1 and conductive layer 6, and can alleviate residual stress upon formation of conductive layer 6, a high reliability of connection can be achieved.

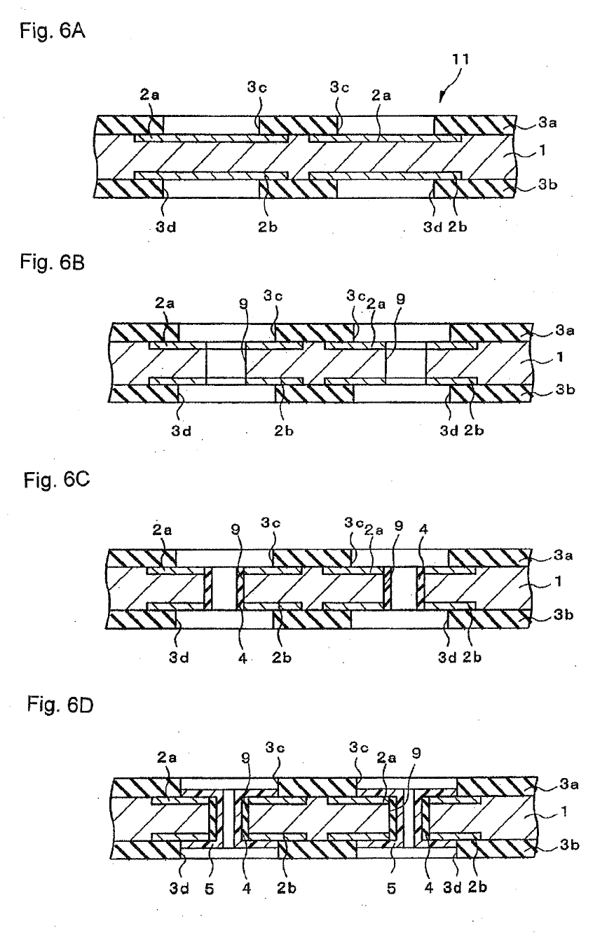

The following description will be given of a method of manufacturing semiconductor device 10 of this exemplary embodiment. FIGS. 6A to 6D are cross-sectional views illustrating the method of manufacturing semiconductor device 10 of this exemplary embodiment showing the sequence of each manufacturing step. First, as illustrated in FIG. 6A, semiconductor chip 11 is provided, where terminal pads 2a and 2b are formed on both surfaces of semiconductor substrate 1, on which elements (not shown) are formed, through insulating layers (not shown), respectively. Passivation films 3a and 3b are formed on the front and back surfaces of this semiconductor chip 11, with openings 3c and 3d in areas immediately above terminal pads 2a and 2b. Next, as illustrated in FIG. 6B, throughholes 9 are formed through semiconductor substrate 1 and terminal pad 2b to connect openings 3c and 3d of semiconductor chip 11 by a dry etching method or a wet etching method.

Next, as illustrated in FIG. 6C, insulating layer 4 made of SiO₂, SiN, SiO, or the like is formed on the inner surfaces of throughholes 9 by natural oxidization, thermal oxidization, CVD method, sputtering method, vacuum vapor deposition method, or the like. Subsequently, as illustrated in FIG. 6D, buffer layer 5 is formed to cover terminal pads 2a and 2b within openings 3c and 3d and to cover insulating layer 4. As a method of forming buffer layer 5, there is, for example, a method which applies a conductive adhesive having a metal filler dispersed in a resin on the front and back surfaces of semiconductor chip 11 using a printing method, an ink jet method, or the like, to deposit the conductive adhesive on the surfaces of terminal pads 2a and 2b within openings 3a and 3b and on the inner surfaces of throughholes 9, and the conductive adhesive then hardens. By applying such a method, buffer layer 5 can be formed at a low cost. In this event, portions where buffer layer 5 is not formed may be previously covered with a resist or the like.

In addition, throughholes of through vias formed through a semiconductor chip that is to be packaged generally have small diameters, for example, diameters of 100 μm or smaller in some cases. For forming such small-diameter vias, buffer layer 5 can be formed using a nano-paste which comprises metal filler 7 having a diameter of 1 μm or smaller and being dispersed in a resin, for example. In this way, buffer layer 5 can be readily formed even when throughholes 9 have a diameter of 100 μm or smaller. In this connection, the nano-paste can be sintered at relatively low temperatures equal to or lower than approximately 150° C.

Next, conductive layer 6 is formed to cover buffer layer 5 by electrolytic plating, non-electrolytic plating, or the like to form the semiconductor device illustrated in FIG. 5A. While a material for forming conductive layer 6 may be, for example, a metal such as Cu, Ni, Pd, Ag, Au, or the like, or an alloy material thereof, when the same material is used as that included in the conductive adhesive layer 5, adherence between buffer layer 5 and conductive layer 6 can be improved. Also, based on the electrolytic plating and non-electrolytic plating, conductive layer 6 which excels in adherence can be formed at low cost. In particular, electrolytic plating can form conductive layer 6 on buffer layer 5 irrespective of the material of metal filler 7.

Further, by using a material whose catalytic activity affects the reducing agent of non-electrolytic plating, for metal filler 7 included in buffer layer 5, adherence between buffer layer 5 and conductive layer 6 can be improved without performing special pre-processing. A material whose catalytic activity affects the reducing agent of non-electrolytic plating may be, for example, a metal having high catalytic activity performance such as Pd, Ni, Cu, Pt, Au, or the like, an alloy material thereof. However, even when a material without catalytic activity is used as metal filler 7, adherence with conductive layer 6 can be improved by performing Pd catalytic processing or the like as pre-processing of non-electrolytic plating. In this connection, the entirety of metal filler 7 need not have catalytic activity which affects the reducing agent of non-electrolytic plating, but a mixture of a metal having catalytic activity performance and a metal not having catalytic activity performance may be used as metal fillers 7. This is effective for reducing cost by limiting the amount of precious metal having high catalytic activity that is used, and for optimizing the adherence and dispersion of the binder with metal filler 7.

Generally, a conductive adhesive material which exhibits higher adherence contains a larger amount of resin, and fails to ensure a sufficient thickness due to contraction during hardening, so that when a throughhole is filled with conductive adhesive, the electric resistance increases within a through via. However, in semiconductor device 10 of this exemplary embodiment, conductive layer 6 made of a metal film is formed on buffer layer 5, which is formed of a conductive adhesive, by a low-cost deposition method such as non-electrolytic plating, electrolytic plating, or the like, so that electric resistance can be reduced within the through via. Also, since semiconductor device 10 of this exemplary embodiment is provided with buffer layer 5 between conductive layer 6 and insulating layer 4, stress can be alleviated between semiconductor substrate 1 and conductive layer 6 to improve reliability of the connection. In particular, when a resin having a low elastic modulus is used as a binder resin of the conductive adhesive which forms buffer layer 5, thermal stress can be alleviated between semiconductor substrate 1 and conductive layer 6, and residual stress can also be alleviated upon formation of conductive film 6.

Further, since buffer layer 5 is formed of a conductive adhesive which includes metal filler 7 which exhibits good adherence with conductive layer 6 and includes binder resin 8 which can ensure adherent strength to insulating layer 4, a good adherent strength can be provided for both insulating layer 4 and conductive layer 6. In particular, when a nano-paste is used as the conductive adhesive, with metal filler 7 having small grain diameters and dispersed in the resin, it is possible to form buffer layer 5 which excels in uniformity and adherence within a throughhole even if the throughhole has a small diameter.

When a metal whose catalytic activity affects the reducing agent of non-electrolytic plating, is used as metal filler 7, no pre-processing is required prior to the formation of conductive layer 6, conductive layer 6 can be deposited by low-cost non-electrolytic plating, and conductive layer 6 can be formed to have a high adherent strength with buffer layer 5. Since non-electrolytic plating exhibits excellent throwing power (uniform electrodeposition properties) to buffer layer 5, defective filling is less likely to occur, and voids are less likely to be formed, as compared with a conventional method in which throughholes are filled with conductive materials such as a soldering paste by printing. Consequently, the non-electrolytic plating can form conductive layer 6 which exhibits a high adherence strength and high reliability. In this event, when the same material as conductive layer 6 is used as metal filler 7, adherence can be further improved between buffer layer 5 and conductive layer 6.

In semiconductor device 10 of this exemplary embodiment, buffer layer 5 is formed of a conductive adhesive which has metal filler 7 dispersed in binder resin 8, but the present invention is not limited to such a construction. For example, instead of the conductive adhesive, a resin material may be used, which has a high adherence to insulating layer 4, though the resin material is not conductive. In this event, after roughening the surface of the buffer layer made of an insulating resin, conductive layer 6 is formed thereon, thereby making it possible to ensure a high adherence between the buffer layer and conductive layer 6 to provide a highly reliable semiconductor device. Likewise, in this semiconductor device, since the buffer layer is provided between conductive layer 6 and insulating layer 4, stress can be alleviated between semiconductor substrate 1 and conductive layer 6. Further, when a resin exhibiting a low elastic modulus is used as the resin material which forms the buffer layer, reliability of the resulting semiconductor device can be further improved.

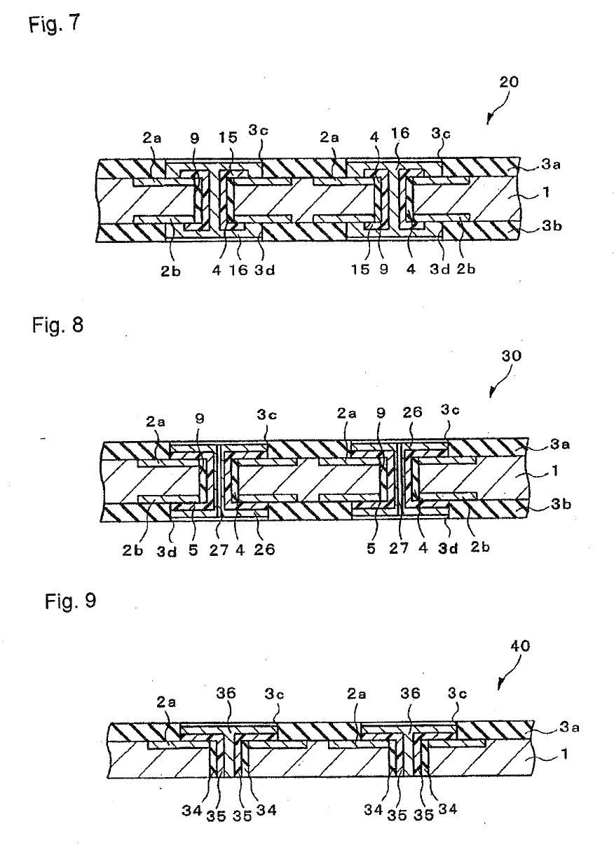

Next, a description will be given of semiconductor device 20 according to a second exemplary embodiment of the present invention. FIG. 7 is a cross-sectional view illustrating the structure of semiconductor device 20 of this exemplary embodiment. In FIG. 7, the same components as those of semiconductor device 10 illustrated in FIGS. 5A, 5B are designated the same reference numerals, and detailed descriptions are omitted.

As illustrated in FIG. 7, in the structure of semiconductor device 20 of this exemplary embodiment, entire surfaces of terminal pads 2a and 2b in openings 3c and 3d are not covered with buffer layer 15, and terminal pads 2a and 2b are partially in contact with conductive layer 16. The adherence of terminal pads 2a and 2b to conductive layer 16 is not as low as the adherence of insulating layer 4 to conductive layer 16. Therefore, by bringing terminal pads 2a and 2b into contact with conductive layer 16, and electrically connecting them, resistance can be reduced within the through vias without reducing adherence.

Next, a description will be given of a method of manufacturing semiconductor device 20 of this exemplary embodiment. Semiconductor device 20 of this exemplary embodiment is formed in the following manner. First, similar to the steps illustrated in FIGS. 6A to 6C, insulating layer 4 is formed within throughholes 9. Subsequently, a conductive adhesive is applied and hardened, while masking those portions of terminal pads 2a and 2b on which buffer layer 15 is not formed, with a resist (not shown) or the like, to form buffer layer 15. After thus forming buffer layer 15, the resist is removed to expose part of the surfaces of terminal pads 2a and 2b. Subsequently, conductive layer 16 is formed by a method similar to the aforementioned semiconductor device 10 of the first exemplary embodiment. In this way, terminal pads 2a and 2b can be directly connected to conductive layer 16. The configuration and advantages in semiconductor device 20 of this exemplary embodiment are similar to the aforementioned semiconductor device 10 of the first exemplary embodiment except for those described above.

Next, a description will be given of semiconductor device 30 according to a third exemplary embodiment of the present invention. FIG. 8 is a cross-sectional view illustrating the structure of semiconductor device 30 of this exemplary embodiment. In FIG. 8, the same components as those of semiconductor device 10 illustrated in FIGS. 5A, 5B are designated the same reference numerals, and detailed descriptions are omitted.

As illustrated in FIG. 8, in the structure of semiconductor device 30 of this exemplary embodiment, throughhole 9 is not completely filled, and hole 27 exists around the center of the through via, i.e., the center of conductive layer 26. This structure is intended to improve productivity because completing filling the interior of throughholes 9 requires a long time and high cost. Specifically, conductive layer 26 is formed so as not to completely fill throughholes 9 therewith. Additionally, in semiconductor device 30 of this exemplary embodiment, holes 27 are can be filled with a resin, solder, or the like to close the through vias, though not shown, after forming the conductive layer 26. The configuration and advantages in semiconductor device 30 of this exemplary embodiment are similar to the aforementioned semiconductor device 10 of the first exemplary embodiment except for those described above.

Next, a description will be given of semiconductor device 40 according to a fourth exemplary embodiment of the present invention. FIG. 9 is a cross-sectional view illustrating the structure of semiconductor device 40 of this exemplary embodiment. In FIG. 9, the same components as those of semiconductor device 10 illustrated in FIGS. 5A, 5B are designated the same reference numerals, and detailed descriptions are omitted.

As illustrated in FIG. 9, semiconductor device 40 of this exemplary embodiment differs from the aforementioned semiconductor device 10 of the first exemplary embodiment in that neither the terminal pad nor the passivation film are formed on the back surface of semiconductor substrate 1. Since this semiconductor device 40 does not require a terminal pad formed on the back surface of semiconductor substrate 1, semiconductor device 40 can be manufactured at a lower cost, as compared with semiconductor substrate 1 provided with terminal pads on both surfaces, as in the aforementioned semiconductor device 10 of the first exemplary embodiment.

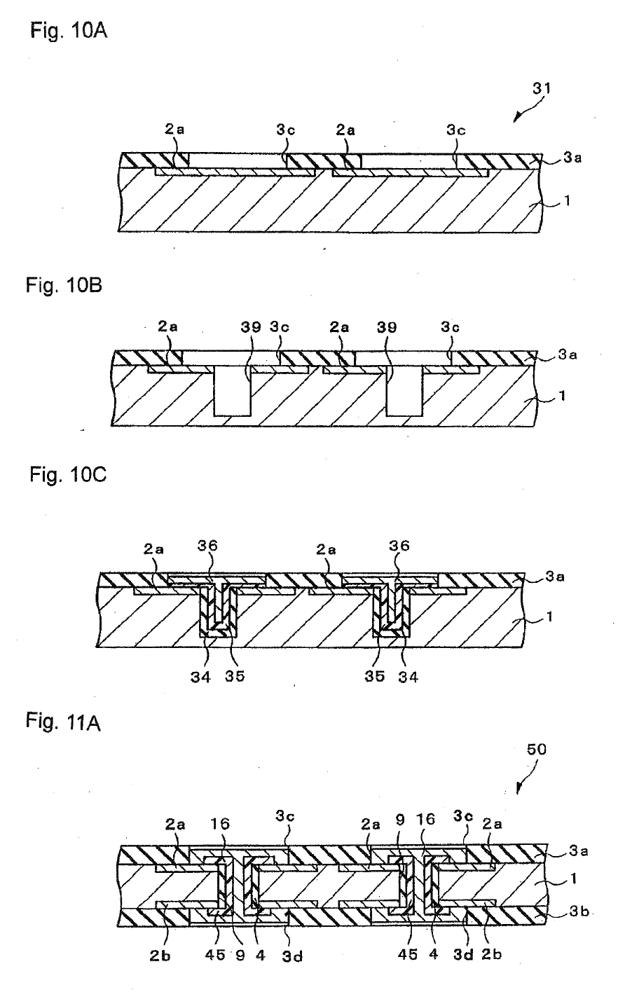

A description will be given of a method of manufacturing semiconductor device 40 of this exemplary embodiment. FIGS. 10A to 10C are cross-sectional views illustrating the method of manufacturing semiconductor device 40 of this exemplary embodiment showing the sequence of each manufacturing step.

First, as illustrated in FIG. 10A, semiconductor chip 31 is provided, where terminal pad 2a is formed only on the front surface of semiconductor substrate 1, on which elements (not shown) are formed, through an insulating layer (not shown). Passivation film 3a is formed on the front surface of this semiconductor chip 31, with opening 3c in an area immediately above terminal pad 2a. Next, as illustrated in FIG. 10B, deep holes 39 are formed inside of opening 3c of semiconductor chip 31 by a dry etching method or a wet etching method. Next, as illustrated in FIG. 10C, insulating layer 34 is formed within deep holes 39 in a step similar to the aforementioned semiconductor device 10 of the first exemplary embodiment, buffer layer 35 is formed to cover insulating layer 34 and terminal pad 2a within openings 3c and 3d, and conductive layer 36 is formed to cover this buffer layer 35. Subsequently, semiconductor substrate 1 is ground from the back surface to remove the bottoms of deep holes 39 to make throughholes, thus forming semiconductor device 40 illustrated in FIG. 9.

When terminal pad 2a is provided only on one surface of semiconductor substrate 1 as semiconductor device 40 of this exemplary embodiment, thick semiconductor substrate 1 may be used, where the back surface is ground to a predetermined thickness after the through vias are formed. Accordingly, as compared with a semiconductor device 10 provided with terminal pads 2a, 2b on both surfaces like semiconductor device 10 illustrated in FIGS. 5A, 5B, semiconductor device 40 provides greater ease in handling because semiconductor substrate 1 can be processed while it is thick. The configuration and advantages in semiconductor device 40 of this exemplary embodiment are similar to the aforementioned semiconductor device 10 of the first exemplary embodiment except for those described above.

Next, a description will be given of a semiconductor device according to a fifth exemplary embodiment of the present invention. FIG. 11A is a cross-sectional view illustrating the structure of semiconductor device 50 of this exemplary embodiment, and FIG. 11B is an enlarged view illustrating a through via thereof. In FIGS. 11A and 11B, the same components as those of semiconductor device 20 illustrated in FIG. 7 are designated the same reference numerals, and detailed descriptions will be omitted.

As illustrated in FIG. 11A, in the structure of semiconductor device 50 of this exemplary embodiment, buffer layer 45 is formed of a non-conductive resin, i.e., insulating resin, and parts of terminal pads 2a and 2b are connected directly to conductive layers 16 in a manner similar to the aforementioned semiconductor device 20 of the second exemplary embodiment. In semiconductor device 50 of this exemplary embodiment, since an ordinary resin can be used as buffer layer 45, instead of a conductive adhesive, the material can be chosen from wider range of materials, and the cost can be reduced.

Also, in semiconductor device 50, asperities are preferably formed on the surface of buffer layer 45, as illustrated in FIG. 11B, in order to ensure adherence between buffer layer 45 and conductive layer 16. Also, when buffer layer 45 is formed of a resin which exhibits a low elastic modulus, conductive layer 16 can be prevented from peeling off, because of the ability to alleviate thermal stress between semiconductor substrate 1 and conductive layer 16 and because of the ability to alleviate residual stress upon formation of conductive layer 16. Accordingly, buffer layer 45 is preferably formed of a resin which exhibits a low elastic modulus.

A method of forming asperities on the surface of buffer layer 45 may be, for example, a method similar to the aforementioned semiconductor device 20 of the second exemplary embodiment, where after forming buffer layer 45 to cover insulating layer 4 and parts of terminal pads 2a and 2b, the surface of buffer layer 45 is roughened by processing based on potassium permanganate, plasma processing, or the like. Then, after a palladium catalyst layer is formed on buffer layer 45, conductive layer 16 is formed on buffer layer 45 by non-electrolytically plating a metal such as Pd, Ni, Cu, Pt, Au, or the like, or an alloy material thereof, to form semiconductor device 50. The configuration and advantages in semiconductor device 50 in this exemplary embodiment are similar to the aforementioned semiconductor device 10 of the first exemplary embodiment except for those described above.

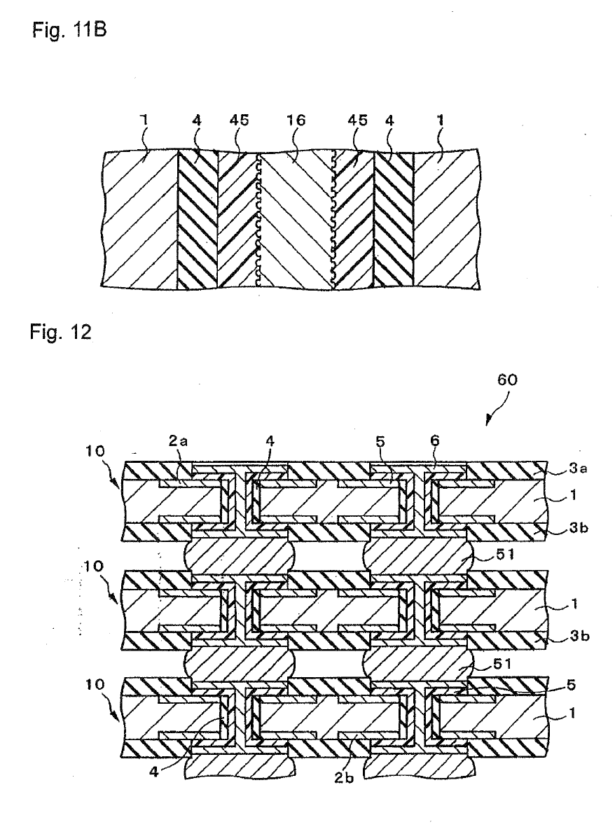

Next, a description will be given of semiconductor package 60 according to a sixth exemplary embodiment of the present invention. FIG. 12 is a cross-sectional view illustrating semiconductor package 60 of this exemplary embodiment. As illustrated in FIG. 12, semiconductor package 60 of this exemplary embodiment comprises a plurality of semiconductor devices 10 illustrated in FIGS. 5A, 5B, which are stacked. The through vias of semiconductors 10 adjoining in the vertical direction are interconnected through solder bumps 51 to electrically connect respective semiconductor devices 10.

Because of the ability to mount a plurality of semiconductor devices 10 in a high density, semiconductor package 60 of this exemplary embodiment is suitable for use in electronic devices such as a mobile telephone, a notebook type personal computer, a desktop type personal computer, a liquid crystal device, an interposer, a module, and the like, and can make up highly reliable electronic devices which meet requirements for reduced size and thickness as well as higher frequencies. While a plurality of the aforementioned semiconductor devices 10 of the first exemplary embodiment are stacked in semiconductor package 60 of this exemplary embodiment, the present invention is not limited to such a construction, and any one or a plurality of the aforementioned semiconductor devices 20, 30, 40, and 50 of the second to fifth exemplary embodiments may be arbitrarily stacked, instead of semiconductor devices 10. In this case, similar advantages can be provided as well.

While the aforementioned first to fifth exemplary embodiments have been described in connection with semiconductor devices which have elements on the surface of semiconductor substrate 1, similar through vias can be formed through a wiring board which does not have elements, like an interposer board, to provide highly reliable wiring boards which can be stacked in multilayer construction.

While the aforementioned first to fifth exemplary embodiments have been described in connection with semiconductor devices which have elements on the surface of semiconductor substrate 1, similar through vias can be formed through a wiring board which does not have elements, like an interposer board, to provide highly reliable wiring boards which can be stacked in multilayer construction. When a plurality of wiring boards are stacked, the stacked wiring boards can be electrically connected to at least one semiconductor device to make up a semiconductor package.

The present invention is not limited to silicon-based wiring board, but can also be applied to a normal printed circuit board, an interposer board made of a flexible material and having wirings, and the like.

Since it has been conventionally difficult to form a conductive layer, which is hard to peel off, on the inner walls of throughholes of a silicon substrate, the present invention is most effective in forming such a conductive layer, which is hard to peel off, in throughholes of a silicon substrate. Also, the present invention is very effective even for throughholes of a resin substrate such as a printed circuit board in a situation in which a conductive layer may break and may cause a disconnection, as is the case with silicon substrate.

1-42. (canceled)

43. A semiconductor device comprising:
a semiconductor substrate;
a first terminal pad formed on a surface of said semiconductor substrate;
a throughhole extending through said first terminal pad and said semiconductor substrate in a thickness direction thereof;
a buffer layer made of a resin and formed to extend from an inner surface of said throughhole to the surface of said semiconductor substrate; said buffer layer having insulating properties, and
a conductive layer formed to cover said buffer layer, said conductive layer extending from above said buffer layer to said first terminal pad, and said conductive layer being directly in contact with said first terminal pad.

44. The semiconductor device according to claim 43, wherein said buffer layer has asperities which are formed on a surface closer to said conductive layer.

45. The semiconductor device according to claim 43, wherein:
a second terminal pad is formed at a position on the back surface of said semiconductor substrate, said position being in alignment to said first terminal pad,
said throughhole is formed to extend through said first terminal pad, said semiconductor substrate, and said second terminal pad, and
said buffer layer is formed to extend from the inner surface of said throughhole to both the front and back surfaces of said semiconductor substrate.

46. The semiconductor device according to claim 45, wherein said conductive layer extends from above said buffer layer to said second terminal pad, and said conductive layer is directly in contact with said second terminal pad.

47. The semiconductor device according to claim 43, wherein said buffer layer is formed of a resin whose elastic modulus is 1 Gpa or less.

48. The semiconductor device according to claim 43, wherein said conductive layer is formed in a tubular shape.

49. A semiconductor package comprising a plurality of semiconductor devices according to claim 43 stacked therein.

50. An electronic device comprising a semiconductor package according to claim 49.

51. The electronic device according to claim 50, wherein said electronic device is a mobile telephone, a notebook type personal computer, a desktop type personal computer, a liquid crystal device, an interposer, or a module.
